(19) United States
(12) Patent Application Publication
(10) Pub. No.: US 2014/0357062 A1
(43) Pub. Date: Dec. 4, 2014

(54) FABRICATING METHOD OF SEMICONDUCTOR DEVICE

(71) Applicant: SAMSUNG ELECTRONICS CO., LTD., Suwon-si (KR)

(72) Inventors: Joong-Han SHIN, Seoul (KR); Bong-Jin KUH, Suwon-si (KR); Tae-Gon KIM, Seoul (KR); Han-Mei CHOI, Seoul (KR); Jeong-Meung KIM, Seoul (KR)

(73) Assignee: SAMSUNG ELECTRONICS CO., LTD., Suwon-si (KR)

(21) Appl. No.: 14/290,171

(22) Filed: May 29, 2014

(30) Foreign Application Priority Data
May 29, 2013 (KR) 10-2013-0061058

(51) Int. Cl. H01L 21/02

(52) U.S. Cl. CPC H01L 21/02592; H01L 21/02667
USPC 438/479

(57) ABSTRACT

A method of fabricating a semiconductor device, the method including forming a trench on a substrate; forming an insulating layer pattern within the trench; depositing an amorphous material on the substrate and the insulating layer pattern; planarizing the amorphous material; removing a portion of the amorphous material, the removed portion of the amorphous material being on an area of the substrate where the trench has been formed; crystallizing remaining portions of the amorphous material into a single crystal material; and planarizing the single crystal material.

### CROSS-REFERENCE TO RELATED APPLICATION

Korean Patent Application No. 10-2013-0061058, filed on May 29, 2013, in the Korean Intellectual Property Office, and entitled: “Fabricating Method Of Semiconductor Device,” is incorporated by reference herein in its entirety.

### BACKGROUND

1. Field

Embodiments relate to a method of fabricating a semiconductor device.

2. Description of the Related Art

An optical device having an optical waveguide may be formed using a Silicon On Insulator (SOI) substrate. The SOI substrate may be composed of a silicon support layer, a silicon oxide layer, and a single crystalline silicon layer. A silicon oxide layer, which may be used as a lower cladding layer, may be formed under the single crystalline silicon on the SOI substrate. An optical device having an optical waveguide may be implemented by forming a core by etching the single crystalline silicon layer of the SOI substrate using a photoresist pattern and then forming an upper cladding layer on the SOI substrate to cover the core.

### SUMMARY

Embodiments are directed to a method of fabricating a semiconductor device.

The embodiments may be realized by providing a method of fabricating a semiconductor device, the method including forming a trench on a substrate; forming an insulating layer pattern within the trench; depositing an amorphous material on the substrate and the insulating layer pattern; planarizing the amorphous material; removing a portion of the amorphous material, the removed portion of the amorphous material being on an area of the substrate where the trench has been formed; crystallizing remaining portions of the amorphous material into a single crystal material; and planarizing the single crystal material.

The method may further include forming an etch stopping layer on the substrate prior to forming the trench.

The etch stopping layer may include a material having an etch selectivity with respect to the substrate.

Forming the insulating layer pattern may include forming an insulating layer material within the trench, and patterning the insulating layer material using the etch stopping layer as a mask.

An upper surface of the insulating layer pattern may be lower than an upper surface of the substrate.

Removing a portion of the amorphous material may include recessing the amorphous material on the area where the trench has been formed using a lithography process.

Crystallizing the amorphous material into the single crystal material may include performing laser annealing, rapid thermal annealing (RTA), spike rapid thermal annealing (SRTA), or flash rapid thermal process (FRTP).

The embodiments may be realized by providing a method of fabricating a semiconductor device, the method including forming an etch stopping layer on a substrate; forming a trench on the substrate; forming an insulating layer pattern within the trench; depositing an amorphous material on the etch stopping layer and the insulating layer pattern; planarizing the amorphous material; removing a portion of the amorphous material, the removed portion of the amorphous material being on an area of the substrate where the trench has been formed; removing the etch stopping layer; crystallizing the amorphous material into a single crystal material; and planarizing the substrate.

The etch stopping layer may include a material having an etch selectivity with respect to the substrate.

Forming the insulating layer pattern may include forming an insulating layer material within the trench, and patterning the insulating layer material using the etch stopping layer as a mask.

An upper surface of the insulating layer pattern may be lower than an upper surface of the etch stopping layer.

Planarizing the amorphous material may include making an upper surface of the amorphous material coplanar with the etch stopping layer.

Removing portions of the amorphous material may include making an upper surface of the amorphous material become lower than an upper surface of the substrate.

Planarizing the substrate may include making an upper surface of the substrate coplanar with an upper surface of the single crystal material.

The method may further include correcting a thickness distribution of the single crystal material by using a location specific process, after planarizing the substrate.

The embodiments may be realized by providing a method of fabricating a semiconductor device, the method including forming an etch stopping layer on a substrate; forming a trench in the substrate; forming an insulating layer pattern within the trench; depositing an amorphous material on the etch stopping layer and the insulating layer pattern; planarizing the amorphous material; removing some of the amorphous material that overlies or is in the trench; crystallizing the amorphous material into a single crystal material.

Forming the insulating layer pattern may include forming an insulating layer material within the trench, and patterning the insulating layer material using the etch stopping layer as a mask.

Planarizing the amorphous material may include making an upper surface of the amorphous material coplanar with the etch stopping layer.

The method may further include removing the etch stopping layer prior to crystallizing the amorphous material into the single crystal material.

The method may further include planarizing the substrate after crystallizing the amorphous material into the single crystal material.

### BRIEF DESCRIPTION OF THE DRAWINGS

Features will be apparent to those of skill in the art by describing in detail exemplary embodiments with reference to the attached drawings in which:

FIGS. 1 to 11 illustrate diagrams showing stages in a method of fabricating a semiconductor device according to an embodiment;

FIGS. 12 to 17 illustrate diagrams showing stages in a method of fabricating a semiconductor device according to another embodiment;

FIG. 18 illustrates a block diagram showing an electronic system including the semiconductor device according to an embodiment; and

FIG. 19 illustrates a block diagram showing an applied example of the electronic system including the semiconductor device according to an embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. Like reference numerals refer to like elements throughout.

It will also be understood that when a layer is referred to as being “on” another layer or substrate, it can be directly on the other layer or substrate, or intervening layers may also be present. In contrast, when an element is referred to as being “directly on” another element, there are no intervening elements present.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The use of the terms “a” and “an” and “the” and similar referents in the context of describing the embodiments (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted.

Unless defined otherwise, all technical and scientific terms used herein have the same meaning as commonly understood by one of ordinary skill in the art to which this application belongs. It is noted that the use of any and all examples, or exemplary terms provided herein is intended merely to better illuminate the embodiments and is not a limitation on the scope unless otherwise specified. Further, unless defined otherwise, all terms defined in generally used dictionaries may not be overly interpreted.

The embodiments will be described with reference to perspective views, cross-sectional views, and/or plan views, in which preferred embodiments may be shown. Thus, the profile of an exemplary view may be modified according to manufacturing techniques and/or allowances. That is, the embodiments are not intended to limit the scope, but rather cover all changes and modifications that can be caused due to a change in manufacturing process. Thus, regions shown in the drawings are illustrated in schematic form and the shapes of the regions are presented simply by way of illustration and not as a limitation.

The method of fabricating a semiconductor device according to an embodiment may help reduce and/or prevent the occurrence of an ablation defect on a buffer layer part through a structural deformation of a device in intermediate operations at the time of re-crystallization for obtaining an epitaxially grown layer. For example, according an embodiment, there is provided a method of forming an inlaid structure for epitaxial growth and then relatively increasing only the thickness of a buffer layer through patterning. When thickness of the buffer layer is increased, if heat energy needed for re-crystallization of amorphous materials is supplied, a rise in temperature to a point higher than the boiling point may be restricted so that an ablation defect may not occur in the buffer layer. According to another embodiment, an inlaid structure may be formed so that a surface of the amorphous materials to be re-crystallized may be set to be formed in a position lower than, e.g., more interior than, a position of a surface of the substrate, and then an etch stopping layer may be removed. In this case, when heat energy is supplied to re-crystallize the amorphous materials, there may be no film for blocking heat transfer to the buffer layer, and thus it may be possible to help reduce the likelihood of and/or prevent the temperature of the buffer layer from rising to a point higher than the boiling point. In addition, a portion of the substrate used as the seed of the epitaxial growth may not be melted, and thus the advantage of the inlaid epitaxial growth may be maintained.

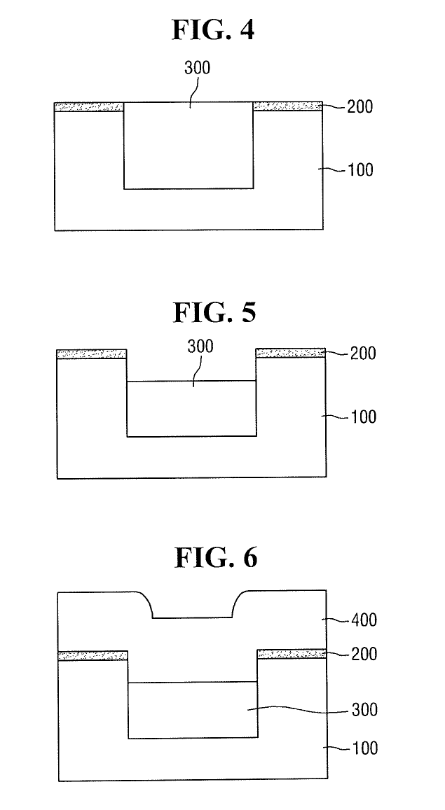

FIGS. 1 to 11 illustrate diagrams showing stages in a method of fabricating a semiconductor device according to an embodiment.

Referring to FIG. 1, an etch stopping layer 200 may be formed on a substrate 100. The substrate 100 may be formed of at least one material selected from the group of Si, Ge, SiGe, GaP, GaAs, SiC, SiGeC, InAs, and InP.

For example, the substrate 100 may be a bulk silicon substrate. The etch stopping layer 200 may include a material having an etch selectivity, e.g., a high etch selectivity, with respect to the substrate. For example, the etch stopping layer 200 may include at least one of silicon nitride (SiN) and a silicon oxynitride. In an implementation, the etch stopping layer 200 may be, e.g., a silicon nitride layer.

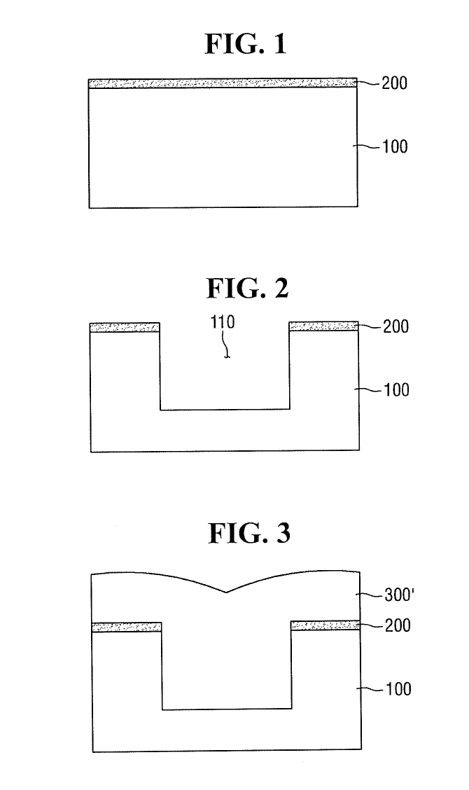

Referring to FIG. 2, a trench 110 may be formed on or in the substrate 100, e.g., on a side where the etch stopping layer 200 has been formed. Part of the substrate 100 may be exposed by patterning the etch stopping layer 200. Then, the substrate 100 may be etched using the etch stopping layer 200 as a mask. For example, the trench 110 may be formed at an exposed portion of the substrate 100, e.g., exposed by the etch stopping layer 200. As noted above, the etch stopping layer 200 may have a high etch selectivity with respect to the substrate 100. Thus, when the exposed portion of the substrate 100 is etched and the trench 110 is formed, the etch stopping layer 200 may not be etched. FIG. 2 illustrates that a sidewall of the trench 110 may be vertical. In an implementation, the trench 110 may have a slanted sidewall.

Referring to FIGS. 3 to 5, an insulating layer pattern 300 may be formed within the trench 110 and on the substrate 100. For example, an insulating layer material 300′ may be formed within the trench 110. As the insulating layer material 300′ is filled in the trench 110, the insulating layer material 300′ may also cover a whole of the etch stopping layer 200. In an implementation, the insulating layer material 300′ may include, e.g., a silicon oxide. In an implementation, some of the insulating layer material 300′ may be removed using a planarization (e.g., CMP) process. For example, the insulating layer material 300′ may be planarized until the etch stopping layer 200 is exposed. Furthermore, an upper or outer part of the insulating layer material 300′ in the trench 110 may be removed, and the insulating pattern 300 may be formed by performing the etching process using the etch stopping layer 200 as a mask. As such, an upper surface of the insulating layer pattern 300 may be lower than an upper surface of the substrate 100. For example, the insulating layer pattern 300 may be contained within the trench 110 such that the insulating layer pattern 300 is contained within outer dimensions of the substrate 100 or is in an interior of the substrate 100.

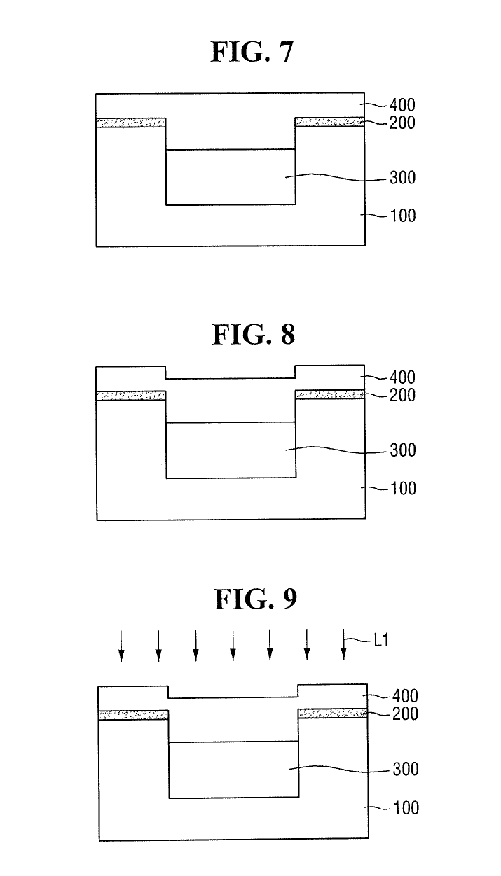

Referring to FIGS. 6 and 7, an amorphous material 400 may be deposited on the etch stopping layer 200 and the insulating layer pattern 300, and the amorphous material 400 may be planarized. For example, the amorphous material 400 may cover the etch stopping layer 200 (formed on the substrate 100) while also filling an empty space within the trench 110. The amorphous material 400 may include, e.g., amorphous silicon. The amorphous material 400 may be planarized to have a planarized surface after depositing the amorphous material 400. The amorphous material 400 may be planarized using, e.g., a partial CMP (chemical mechanical polishing) process. As such, the amorphous material 400 may remain on the etch stopping layer 200. The amorphous material 400 that remains on the etch stopping layer 200 may serve as a heat energy absorption layer in a subsequent process for crystallizing the amorphous material 400 that is in the trench 110. Deformation of the substrate 100 and the etch stopping layer 200 by stress applied in the subsequent process may be reduced and/or prevented due to the absorption of heat energy by the amorphous material 400 that remains on the etch stopping layer 200.

In an implementation, the method of fabricating a semiconductor device according to an embodiment may include removing some of the amorphous material 400 that is on an area where the trench 110 has been formed, e.g., some of the amorphous material 400 that overlies the trench 110 may be removed, and may continue the following process of supplying heat energy unlike the existing process. Thus, an amount of the amorphous material 400 that is removed by the planarization (e.g., CMP) process may be reduced, and a thickness of the amorphous material 400 remaining on the etch stopping layer 200 may be significant, so that the etch stopping layer 200 may not be deformed by heat energy transmission.

Referring to FIG. 8, some of the amorphous material 400 on the area where the trench 110 has been formed may be removed. For example, portions of the amorphous material 400 that overlie the trench 110 may be removed. After the amorphous material 400 on the area where the trench 110 has been formed is melted, e.g., in order to convert the melted amorphous material 400 into a single crystal material 400′ by crystallization through epitaxial growth, an appropriate thickness may be needed to supply sufficient heat energy to the amorphous material 400 on the area where the trench 110 has been formed. Hence, a process of removing some of the amorphous material 400 on the area where the trench 110 has been formed may be needed. Thus, the amorphous material 400 on the area where the trench 110 has been formed may be set to be exposed to light using a photoresist pattern (not illustrated), the photoresist pattern may be removed, and then the amorphous material 400 on the area where the trench 110 has been formed may be recessed using the etching process.

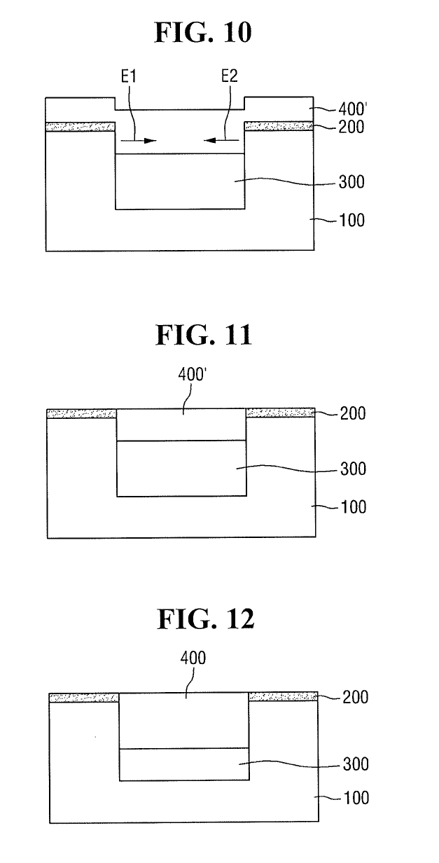

Referring to FIGS. 9 and 10, the amorphous material 400 may be crystallized to form a single crystal material 400′. For example, a laser L1 may be emitted toward the amorphous material 400. For example, heat energy may be supplied to the amorphous material 400 using laser annealing, and the signal crystal material 400′ may be formed by crystallization through epitaxial growth. In an implementation, heat energy may be supplied to the amorphous material 400 using, e.g., rapid thermal annealing (RTA), spike rapid thermal annealing (SPTA), or a flash rapid thermal process (FRTP). If heat energy is supplied to the amorphous material 400, the amorphous material 400 may be melted, and then both sidewalls of the trench 100 may become the seed so that epitaxial growth occurs through crystallization toward a center (e.g., in E1 and E2 directions) of the trench 110.

Referring to FIG. 11, the single crystal material 400′ may be planarized. The single crystal material 400′ may be planarized using, e.g., a CMP process. After the single crystal material 400′ is formed, the single crystal material 400′ may be planarized and at least partially removed until the etch stopping layer 200 is exposed. For example, after the epitaxial growth occurs, a surface of the single crystal material 400′ may be unevenly formed. Thus, surface of the single crystal material 400′ may be evened out by using the planarization (e.g., CMP) process.

Hereinafter, a method of fabricating a semiconductor device according to another embodiment will be described.

FIGS. 12 to 17 illustrate diagrams showing stages in a method of fabricating a semiconductor device according to another embodiment.

Referring to FIGS. 1 to 6 and 12, first, an etch stopping layer 200 may be formed on a substrate 100. The substrate 100 may be formed of at least one of, e.g., Si, Ge, SiGe, GaP, GaAs, SiC, SiGeC, InAs, or InP. For example, the substrate 100 may be a bulk silicon substrate. The etch stopping layer 200 may include a material having a high etch selectivity with respect to the substrate. For example, the etch stopping layer 200 may include at least one of silicon nitride (SiN) or a silicon oxynitride. The etch stopping layer 200 may be, e.g., a silicon nitride layer.

Then, a trench 110 may be formed in the substrate 100 where the etch stopping layer 200 has been formed, e.g., in or on the side of the substrate 100 that includes the etch stopping layer 200 thereon. Part of the substrate 100 may be exposed by patterning the etch stopping layer 200, and then the substrate 100 may be etched using the etch stopping layer 200 as a mask. At this time, the trench 110 may be formed at an exposed portion of the substrate 100, e.g., at a portion of the substrate 100 exposed by the etch stopping layer 200. The etch stopping layer 200 may have a high etch selectivity with respect to the substrate 100, and thus when the exposed portion of the substrate 100 is etched and the trench 110 is formed, the etch stopping layer 200 may not be etched. FIG. 2 illustrates that the sidewall of the trench 110 may be vertical, but, in an implementation, the trench 110 may have a slanted sidewall.

Thereafter, an insulating layer pattern 300 may be formed within the trench 110 in the substrate 100. First, insulating layer material 300′ may be formed within the trench 110. As the insulating layer material 300′ is filled in the trench 110, the insulating layer material 300′ may also cover all of the etch stopping layer 200. The insulating layer material 300′ may include, e.g., a silicon oxide. Portions of the insulating layer material 300′ may be removed using a planarization (e.g., CMP) process. At this time, the insulating layer material 300′ may be planarized until the etch stopping layer 200 is exposed. Then, an upper part of the insulating layer material 300′ in the trench 110 may be removed, and the insulating pattern 300 may be formed by performing an etching process using the etch stopping layer 200 as a mask. As such, an upper or outer surface of the insulating layer pattern 300 may be lower than, e.g., internal to, the upper or outer surface of the substrate 100. For example, the upper surface of the insulating layer pattern 300 of the present embodiment may be lower than, e.g., may be further from an opening of the trench 110 than, an upper surface of the insulating layer pattern 300 in the previous embodiment.

Then, amorphous material 400 may be deposited on the etch stopping layer 200 and the insulating layer pattern 300, and the amorphous material 400 may be planarized. For example, the amorphous material 400 may cover the etch stopping layer 200 on the substrate 100 while filling an empty space within the trench 110. The amorphous material 400 may include, e.g., amorphous silicon. The amorphous material 400 may be planarized to have the planarized surface after depositing the amorphous material 400. The amorphous materials 400 may be planarized using a partial CMP (chemical mechanical polishing) process. At this time, portions of the amorphous materials 400 may be removed until the etch stopping layer 200 is exposed. For example, an upper surface of the amorphous materials 400 may be set to coincide with, e.g., may be coplanar with, the upper surface of the etch stopping layer 200 in order to later be able to remove some of the amorphous material 400 on the area where the trench has been formed 110, e.g., overlying or in the trench 110, using the etch stopping layer 200 as a mask. Hence, the material of the etch stopping layer 200 may have a high etch selectivity with respect to the amorphous material 400 (e.g., amorphous silicon).

Referring to FIG. 13, some of the amorphous material 400 on the area where the trench 110 has been formed or in the trench 110 may be removed. After the amorphous material 400 (on the area where the trench 110 has been formed or in the trench 110) is melted, in order to convert the melted amorphous material 400 into a single crystal material 400′ by crystallization through epitaxial growth, an appropriate thickness may be needed to supply sufficient heat energy to the amorphous material 400 on the area where the trench 110 has been formed or in the trench 110. Hence, a process of removing some of the amorphous material 400 on the area where the trench 110 has been formed or in the trench 110 may be desirable. To this end, some of the amorphous material 400 on the area where the trench 110 has been formed may be removed using the etch stopping layer 200 as a mask. Hence, the material of the etch stopping layer 200 may have an etch selectivity, e.g., a high etch selectivity, with respect to the amorphous material 400 (e.g., amorphous silicon). The upper surface of the amorphous material 400 may be set to be lower than the upper surface of the substrate 100 by recessing the amorphous material 400 on or overlying the area where the trench 110 has been formed or in the trench 110. For example, the amorphous material 400 may be internal to surfaces of the substrate, or may have outer surfaces that are closer to a center of the substrate 100 than the outer surfaces of the substrate 100 are to the center of the substrate 100.

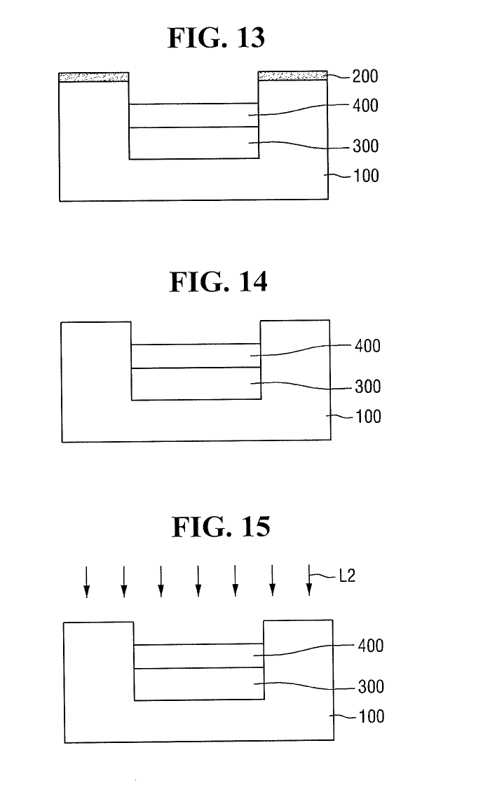

Referring to FIG. 14, the etch stopping layer 200 may be removed. If the etch stopping layer 200 is removed, the upper surface of the substrate 100 (e.g., a bulk silicon substrate) may be exposed. When heat energy is supplied to the amorphous material 400 in a subsequent step, the heat energy may also be supplied to the substrate 100. In this case, heat energy absorbed in the upper part of the substrate 100 may be transferred in the depth direction of the substrate 100. Thus, a rise in temperature in the upper part of the substrate 100 to a point higher than the boiling point of the materials of the substrate 100 may be prevented. If the etch stopping layer 200 is not removed, the etch stopping layer 200 may disturb smooth (e.g., heat) transfer of the materials of the substrate 100, the temperature of the upper part of the substrate 100 may rise to a point higher than the boiling point of the materials of the substrate 100, and an undesirable ablation defect may occur in the upper part of the substrate 100.

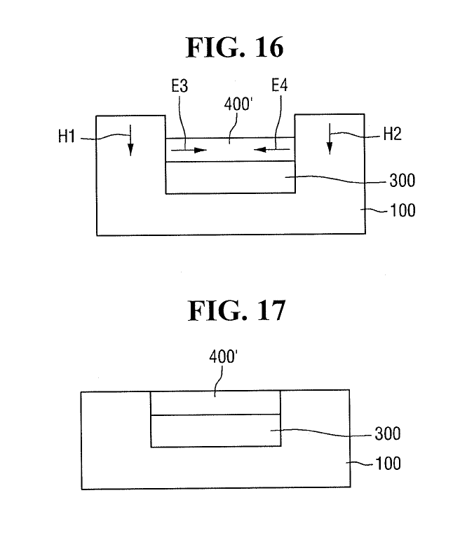

Referring to FIGS. 15 and 16, the amorphous material 400 may be crystallized as or into a single crystal material 400′. For example, a laser L2 may be emitted toward the amorphous material 400. For example, heat energy may be supplied to the amorphous material 400 using laser annealing, and the single crystal material 400′ may be formed by crystallizing through epitaxial growth. In an implementation, heat energy may be supplied to the amorphous material 400 using rapid thermal annealing (RTA), spike rapid thermal annealing (SPTA), or a flash rapid thermal process (FRTP). If heat energy is supplied to the amorphous material 400, the amorphous material 400 may be melted, and then both sidewalls of the trench 100 may become the seed so that epitaxial growth may occur through crystallization toward the center (e.g., in directions E3 and E4) of the trench 110. Furthermore, heat energy transferred to the upper part of the substrate 100 may be transferred in the depth direction H1 and H2 of the substrate 100. Thus, an increase in the temperature of materials of the substrate 100 to a point higher than the boiling point may be prevented.

Referring to FIG. 17, the substrate 100 may be planarized. The upper part of the substrate 100 may be planarized using, e.g., a CMP process. At this time, the upper surface of the substrate 100 may be set to coincide with, e.g., may be coplanar with, the upper surface of the signal crystal material 400′. In addition, after the substrate 100 is planarized, a thickness distribution of the single crystal material 400′ may be corrected using location specific processing (LSP). The LSP is a process of removing a portion that exceeds a predetermined thickness by scanning an etching ion beam in order to adjust the thickness of the substrate (e.g., a silicon substrate). The etching ion beam may be generated by CHF₃/O₂ plasma, and may be provided toward the substrate.

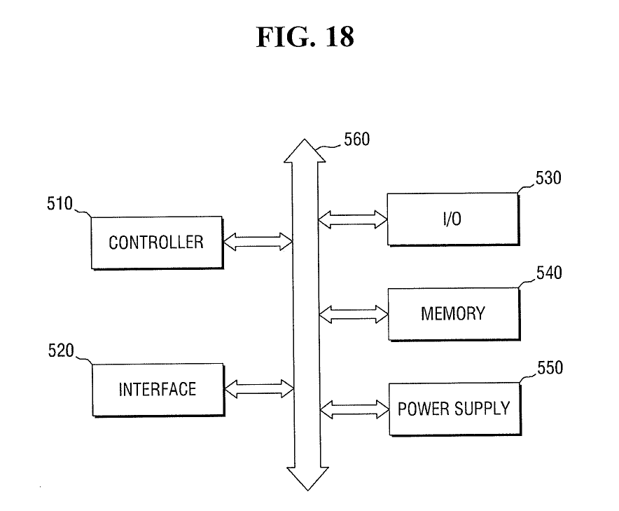

Hereinafter, an electronic system including a semiconductor device according to some embodiments will be described. FIG. 18 illustrates a block diagram schematically showing an electronic system including the semiconductor device according to an embodiment.

Referring to FIG. 18, the electronic system may include a controller 510, an interface 520, an input/output (I/O) unit 530, a memory 540, a power supply 520 and a bus 560.

The controller 510, the interface 520, the I/O unit 530, the memory 540, and the power supply 520 may be combined through the bus 560. The bus 560 is a path through which data are transmitted.

The controller 510 may process data including at least one of a microprocessor, a microcontroller and logic devices capable of performing functions similar to those of the microprocessor and the microcontroller.

The interface 520 may perform a function of transmitting data to a communication network or receiving data from the communication network. The interface 520 may be wired or wireless. For example, the interface 520 may include an antenna or a wired/wireless transceiver, etc.

The I/O unit 530 may include a keypad and a display device, and may input and output data.

The memory 540 may store data and/or commands, etc. The semiconductor device according to an embodiment may be provided as some components of the memory 540.

The power supply 550 may convert externally-input power and supply the converted power to respective components 510 to 540.

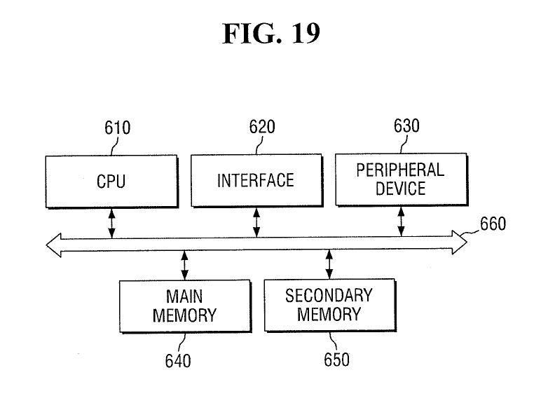

FIG. 19 illustrates a block diagram schematically showing an applied example of the electronic system including the semiconductor device according to an embodiment.

Referring to FIG. 19, the electronic system may include a central processing unit (CPU) 610, an interface 620, a peripheral device 630, a main memory 630, a secondary memory 650, and a bus 660.

The CPU 610, the interface 620, the peripheral device 630, the main memory 640, and the peripheral memory 650 may be combined through the bus 660. The bus 660 corresponds to a path through which data is moved.

The CPU 610 may include a controller and a calculation unit, and may perform a program and process data.

The interface 620 may transmit data to a communication network and receive data from the communication network. The interface 620 may be wired or wireless. For example, the interface 620 may include an antenna or a wired/wireless transceiver, etc.

The peripheral device 630 may include a mouse, a keyboard, a display, and a printer, and may input and output data.

The main memory 640 may transmit data to the CPU 610 and receive data from the CPU 610, and may store data and/or commands needed for performing a program. The semiconductor device according to an embodiment may be provided as some components of the main memory 640.

The secondary memory 650 may include non-volatile storage devices such as a magnetic tape, a magnetic disk, a floppy disk, a hard disk, and an optical disk, and may store data and/or commands, etc. The secondary memory 650 may store data even when power of the electronic system is blocked.

In an implementation, a semiconductor device according to an may be provided as one of various components of an electronic device, such as a computer, a ultra mobile PC, a workstation, a netbook, a personal digital assistant (PDA), a portable computer, a web tablet, a wireless phone, a mobile phone, a smart phone, an e-book, a portable multimedia player, a portable game console, a navigation system, a black box, a digital camera, a 3-dimensional television, a digital audio recorder, a digital audio player, a digital picture recorder, a digital picture player, a digital video recorder, a digital video player, a device capable of transmitting and receiving information in a wireless environment, one of various electronic devices that constitute a home network, one of various electronic devices that constitute a computer network, one of various electronic devices that form a telemetics network, an RFID device, and one of various components that constitute a computing system.

By way of summation and review, a SOI substrate may be more expensive than a bulk silicon wafer, and thus there may be a limit in commercialization. Furthermore, in the case of an optical device having an optical waveguide implemented on the SOI substrate, it may be difficult to integrate, on a single substrate, electric devices such as the optical device having the optical waveguide implemented on the SOI and a dynamic random access memory (DRAM) implemented on a bulk silicon.

When fabricating a coupler and a waveguide of an optical device, a silicon layer, which may be epitaxially grown based on the bulk silicon wafer, may be used. Likewise, a solid phase epitaxy (SPE) process and a liquid phase epitaxy (LEG) process may be used to obtain the epitaxially grown silicon layer. For example, cross-sectional structures of devices fabricated using the liquid phase epitaxy (LEG) process may be divided into an overlaid structure and an inlaid structure. Here, the growth length at the time of epitaxial growth by the overlaid structure may be smaller than the growth length at the time of epitaxial growth by the inlaid structure, and thus the inlaid structure may be mainly used.

The embodiments may provide a method of fabricating a semiconductor device capable of preventing occurrence of an ablation defect in a buffer layer when fabricating the semiconductor device by using a liquid phase epitaxy (LEG) process.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A method of fabricating a semiconductor device, the method comprising:
forming a trench on a substrate;
forming an insulating layer pattern within the trench;
depositing an amorphous material on the substrate and the insulating layer pattern;
planarizing the amorphous material;
removing a portion of the amorphous material, the removed portion of the amorphous material being on an area of the substrate where the trench has been formed;
crystallizing remaining portions of the amorphous material into a single crystal material; and
planarizing the single crystal material.

2. The method as claimed in claim 1, further comprising forming an etch stopping layer on the substrate prior to forming the trench.

3. The method as claimed in claim 2, wherein the etch stopping layer includes a material having an etch selectivity with respect to the substrate.

4. The method as claimed in claim 3, wherein forming the insulating layer pattern includes:
forming an insulating layer material within the trench, and
patterning the insulating layer material using the etch stopping layer as a mask.

5. The method as claimed in claim 1, wherein an upper surface of the insulating layer pattern is lower than an upper surface of the substrate.

6. The method as claimed in claim 1, wherein removing a portion of the amorphous material includes recessing the amorphous material on the area where the trench has been formed using a lithography process.

7. The method as claimed in claim 1, wherein crystallizing the amorphous material into the single crystal material includes performing laser annealing, rapid thermal annealing (RTA), spike rapid thermal annealing (SRTA), or flash rapid thermal process (FRTP).

8. A method of fabricating a semiconductor device, the method comprising:
forming an etch stopping layer on a substrate;
forming a trench on the substrate;
forming an insulating layer pattern within the trench;
depositing an amorphous material on the etch stopping layer and the insulating layer pattern;
planarizing the amorphous material;
removing a portion of the amorphous material, the removed portion of the amorphous material being on an area of the substrate where the trench has been formed;
removing the etch stopping layer;
crystallizing the amorphous material into a single crystal material; and
planarizing the substrate.

9. The method as claimed in claim 8, wherein the etch stopping layer includes a material having an etch selectivity with respect to the substrate.

10. The method as claimed in claim 9, wherein forming the insulating layer pattern includes:
forming an insulating layer material within the trench, and
patterning the insulating layer material using the etch stopping layer as a mask.

11. The method as claimed in claim 8, wherein an upper surface of the insulating layer pattern is lower than an upper surface of the etch stopping layer.

12. The method as claimed in claim 8, wherein planarizing the amorphous material includes making an upper surface of the amorphous material coplanar with the etch stopping layer.

13. The method as claimed in claim 8, wherein removing portions of the amorphous material includes making an upper surface of the amorphous material become lower than an upper surface of the substrate.

14. The method as claimed in claim 8, wherein planarizing the substrate includes making an upper surface of the substrate coplanar with an upper surface of the single crystal material.

15. The method as claimed in claim 8, further comprising correcting a thickness distribution of the single crystal material by using a location specific process, after planarizing the substrate.

16. A method of fabricating a semiconductor device, the method comprising:
forming an etch stopping layer on a substrate;
forming a trench in the substrate;
forming an insulating layer pattern within the trench;
depositing an amorphous material on the etch stopping layer and the insulating layer pattern;
planarizing the amorphous material;
removing some of the amorphous material that overlies or is in the trench;
crystallizing the amorphous material into a single crystal material.

17. The method as claimed in claim 16, wherein forming the insulating layer pattern includes:
forming an insulating layer material within the trench, and
patterning the insulating layer material using the etch stopping layer as a mask.

18. The method as claimed in claim 16, wherein planarizing the amorphous material includes making an upper surface of the amorphous material coplanar with the etch stopping layer.

19. The method as claimed in claim 16, further comprising removing the etch stopping layer prior to crystallizing the amorphous material into the single crystal material.

20. The method as claimed in claim 16, further comprising planarizing the substrate after crystallizing the amorphous material into the single crystal material.
